(19) United States
(12) Patent Application Publication
(10) Pub. No.: US 2005/0206927 A1
(43) Pub. Date: Sep. 22, 2005

(54) Color conversion technique for printing apparatus

(76) Inventor: Kazumi Yamada, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/075,315

(22) Filed: Mar. 7, 2005

(30) Foreign Application Priority Data
Mar. 8, 2004 (JP) 2004-64307
Mar. 16, 2004 (JP) 2004-73985

(51) Int. Cl. G06F 15/00; G03F 3/08

(52) U.S. Cl. 358/1.9; 358/518; 382/167

(57) ABSTRACT

A color conversion method for converting color in a first color system representing color of input image data to color in a second color system representing amounts of a plurality of inks used for printing is provided. The method comprises the steps of: providing a color conversion lookup table for use in converting color component values of the first color system to color component values of the second color system; and executing color conversion to generate an output value consisting of color component values of the second color system from an input value consisting of color component values of the first color system by referencing the color conversion lookup table, wherein a same output value is generated from different input values representing different colors in predetermined color range of color in the first color system.

### CROSS-REFERENCE TO RELATED APPLICATIONS

The present application claims the priority based on Japanese Patent Application No. 2004-64307 filed on Mar. 8, 2004 and No. 2004-73985 filed on Mar. 16, 2004 the disclosure of which is hereby incorporated herein by reference in its entirety.

### BACKGROUND OF THE INVENTION

1. Field of the Invention

The present invention relates to a technique for color conversion from color representing a image data to color representing ink amounts.

2. Description of the Related Art

When making a copy by using a scanner/printer/copier complex or an image processing system with a scanner and printer, a process of acquiring an image data by means of scanning an original and a process of outputting the acquired image data to the printer are performed.

When outputting the image data acquired by a scanner to a printer, there are cases that areas such as text with black in the original are not output in black as used in the original, but rather output in a chromatic color. Also, when outputting an original that contains areas of specific colors other than black, the are cases that areas in a specific color in the original are output in different colors from the specific color. Hereinafter, color adjustment to output specific color as specific color in the original is also called “specific color correction”. To reduce outputting of colors that are originally a specific color as a different color from the specific color in this way, image processing such as adjustment of contrast or color balance is performed, for example.

When outputting the image data acquired by a scanner to a printer, there is another problem. In general, the original is created by outputting a source image on a paper as the printing medium. When the lightness of the paper is not high enough, there are cases when a light gray color (hereafter called “background noise image”) appears on the background of the area that shows the source image with image data for which the original was read by a scanner. Because of this, due to the background noise image, there are cases when the area of the paper that was originally white is not white when the image data read by a scanner is output to a printer. This kind of background noise image can be reduced by image processing such as adjustment of the contrast and level of the overall image data Performing of such a image processing (generally, such a image processing to remove the background noise is called “background removal”) makes the color of the background noise image white.

However, when these image processing are performed for an area which is not in the specific color or not background noise in the original, the image processing may cause unexpected change in color.

### SUMMARY OF THE INVENTION

An object of the present invention is to perform image processing for specific color correction and background removal, while reducing unexpected change in color.

According to an aspect of the present invention, a color conversion method for converting color in a first color system representing color of input image data to color in a second color system representing amounts of a plurality of inks used for printing is provided. The method comprises the steps of: providing a color conversion lookup table for use in converting color component values of the first color system to color component values of the second color system; and executing color conversion to generate an output value consisting of color component values of the second color system from an input value consisting of color component values of the first color system by referencing the color conversion lookup table, wherein a same output value is generated from different input values representing different colors in predetermined color range of color in the first color system.

According to this arrangement, the color conversion method provides functions of image processing for specific color correction and background removal. On the other hand, since the image processing is applied for the colors in predetermined color range, unexpected change in color is reduced.

The invention can be realized in various embodiments, such as an image processing method or an image processing device, a printing method or a printing device, and a computer program for executing the functions of these methods or devices and a recording medium on which are recorded such computer programs, and data signals embedded in carrier waves including such computer programs.

These and other objects, features, aspects, and advantages of the present invention will become more apparent from the following detailed description of the preferred embodiments with the accompanying drawings.

### BRIEF DESCRIPTION OF THE DRAWINGS

FIG. 1 is an explanatory diagram that shows the arrangement of the scanner, printer, and copier combined machine 100.

FIGS. 2A to 2C illustrate the operating panel 300 during the settings of the SPC complex 100 by the operation of the operating panel 300.

FIG. 3 is a block diagram that shows the arrangement of the printing data generating unit 220 in the first embodiment.

FIG. 4 is a flowchart of the procedure for generating the internal image data rgb by the color adjustment unit 240.

FIGS. 5A and 5B illustrate the results of the color adjustment process.

FIG. 6 is a block diagram that shows the arrangement of the printing data generating unit 220a in the second embodiment.

FIG. 7 is a flowchart of the procedure for generation of a color conversion lookup table LUT by the lookup table generating unit 242 in the second embodiment.

FIGS. 8A and 8B illustrate the results of the process of generating the color conversion lookup table LUT in the second embodiment.

FIG. 9 is a flowchart of the procedure for generation of a color conversion lookup table by the lookup table generation unit 242 in the third embodiment.

FIG. 10 illustrates the results of the process of generating the color conversion lookup table LUT in the third embodiment.

FIGS. 11A to 11C illustrate the operating panel 300 during the settings of the SPC complex 100 in the fourth embodiment.

FIG. 12 is a flowchart of the procedure for generating the internal image data rgb by the color adjustment unit 240 in the fourth embodiment.

FIGS. 13A and 13B illustrate the results of the color adjustment process.

FIG. 14 shows the tone curve TC that is used for color adjustment of the target pixel in the fourth embodiment.

FIG. 15 is a flowchart of the procedure for generation of a color conversion lookup table LUT by the lookup table generating unit 242 in the fifth embodiment.

FIG. 16 illustrates the result of the process of generating a color conversion lookup table LUT in the fifth embodiment.

FIG. 17 shows variations of the tone curve used for the tone conversion.

### DESCRIPTION OF THE PREFERRED EMBODIMENT

Preferred embodiments of the invention are illustrated with examples in the following order.
A. Embodiment 1:
B. Embodiment 2:
C. Embodiment 3:
D. Embodiment 4:
E. Embodiment 5:
F. Variations of Tone Curve:
G. Modifications:

A. Embodiment 1:

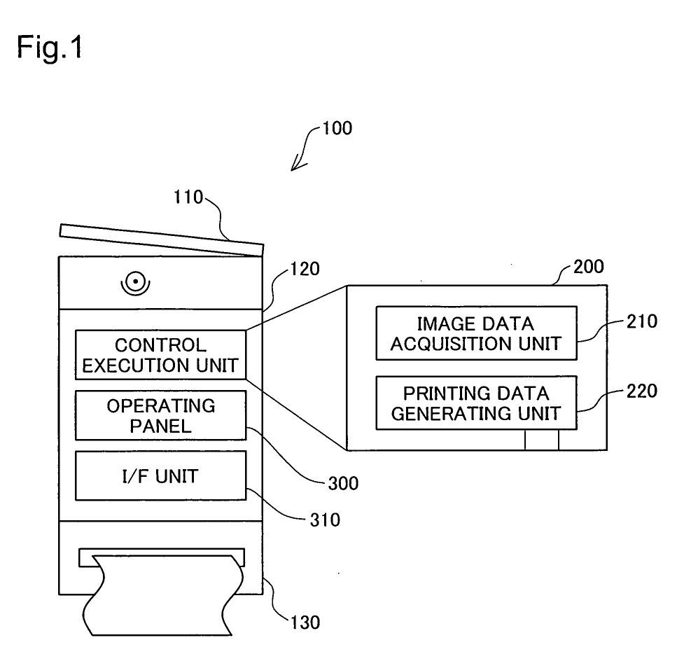

FIG. 1 is an explanatory diagram that shows the arrangement of the scanner, printer, and copier combined machine 100 (hereafter called “SPC complex 100”) as an embodiment of the present invention. The SPC complex 100 comprises a scanner 110, a printer 130, and a controller 120 for controlling the scanner 110 and the printer 130.

The scanner 110 has a light source that illuminates the original. The original reflects the light to a CCD and the CCD converts reflected light intensity to electric signal. The CCD output signal is converted to digital signal by an A/D converter. In this way the source image data is generated.

The printer 130 is an inkjet printer that forms images by ejecting multiple colors of ink onto a printing medium such as paper, etc. The printer 130 ejects ink onto the printing medium according to the printing data supplied from the control unit 120. A color image is formed on the printing medium by forming color points (ink dots) depending on the ejected ink amount.

The controller 120 has a control execution unit 200, an operating panel 300, and an I/F unit 310. The I/F unit functions as an interface with an external computer. The control execution unit 200 is configured as a micro computer having a CPU, ROM, RAM, etc. The control execution unit 200 includes an image data acquisition unit 210 and a printing data generating unit 220. The functions of each of these units 210 and 220 are realized by execution of the computer program stored on ROM with the CPU.

The image data acquisition unit 210 generates image data (RGB image data) represented by the RGB color system by performing image processing of the source image data supplied from the scanner 110. The generated RGB image data is supplied to either the printing data generating unit 220 or the I/F unit 310 according to the operating mode of the SPC complex 100.

RGB image data is supplied to the printing data generating unit 220 from either the image data acquisition unit 210 or the I/F unit 310 according to the operating mode of the SPC complex 100. The printing data generating unit 220 generates printing data that represents the ink amount for each of multiple colors of ink used for printing with the printer 130. The ink amount is determined in accordance with the supplied RGB image data. This printing data can be called image data represented by the color system corresponding to the ink amount.

The operating panel 300 has an operating button that acquires input from a user. The operating panel 300 also has a display device for displaying information on the SPC complex 100 such as operating mode and setting values. The user can change the operating mode or setting values of the SPC complex 100 by pressing the operating button while viewing the setting information displayed on the display device.

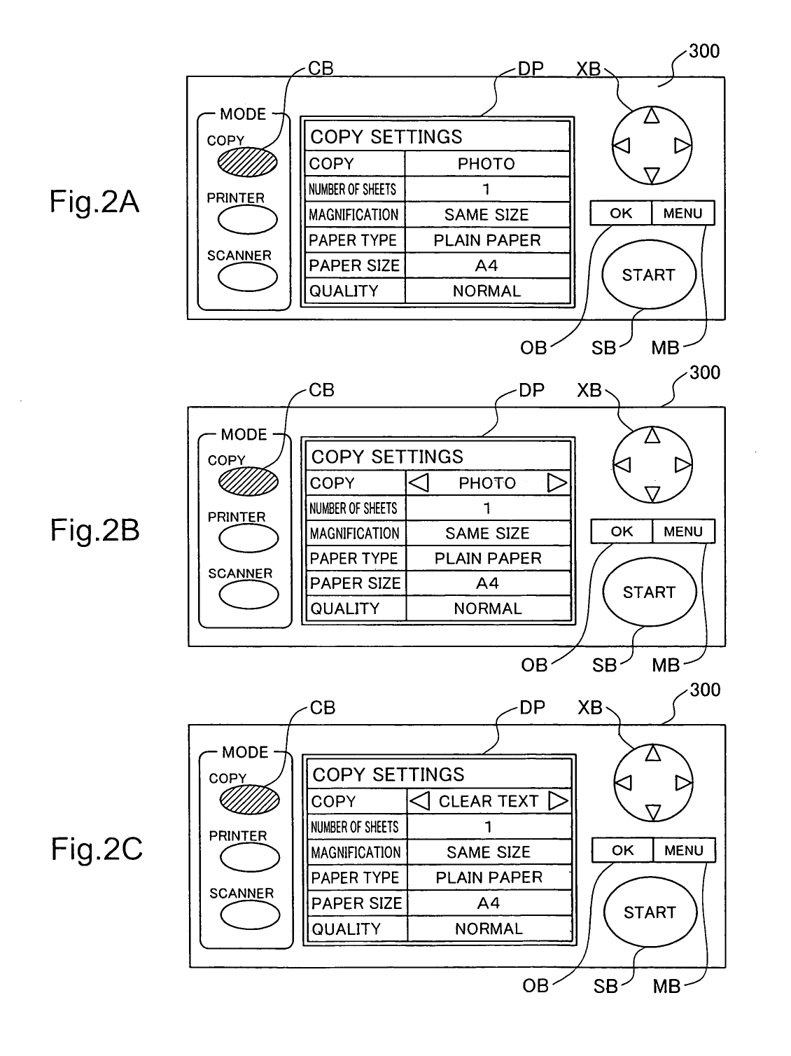

FIGS. 2A to 2C illustrate the operating panel 300 during the settings of the SPC complex 100 by the operation of the operating panel 300. The operating panel 300 has operating buttons such as copy button CB and start button SB, and has a display device DP.

FIG. 2A shows the operating panel 300 when the user selects the copy mode as the operating mode of the SPC complex 100 by pushing the copy button CB. The text “COPY SETTING” is displayed on the display device DP. The displayed text indicates that it is possible to change various settings in the copy mode. The setting item such as “COPY,” “PAGE COUNT,” and “MAGNIFICATION,” and the setting values of each of the setting items are also displayed.

FIG. 2B shows the operating panel 300 when the user presses the menu button MB for changing the setting values in copy mode. By the menu button MB being pressed, triangles are displayed at the left and right of the setting value. The triangles indicate that the setting value can be changed. The setting item to be changed is selected by pressing the selection button XB up and down. The setting value of the selected setting item is changed by the user pressing the selection button XB left and right.

FIG. 2C shows the operating panel 300 when the “COPY” setting, which is a setting item to specify a type of copy in the copy mode setting items, is changed. In the example of FIG. 2C the setting value of the “COPY” mode is changed from the “PHOTO” mode to the “CLEAR TEXT” mode. After the setting value of each setting item is changed in this way, when the user presses the OK button OB, the changed setting value is supplied to the control execution unit 200 (FIG. 1). The control execution unit 200 stores the supplied setting values on a temporary storage device such as RAM.

Execution of copying is started by the user pressing the start button SB. When the start button SB is pressed, the image data acquisition unit 210 (FIG. 1) acquires the RGB image data that represents the image of the original placed on the document table of the scanner 110 (FIG. 1). The acquired RGB image data is converted to printing data by the printing data generating unit 220, and is supplied to the printer 130.

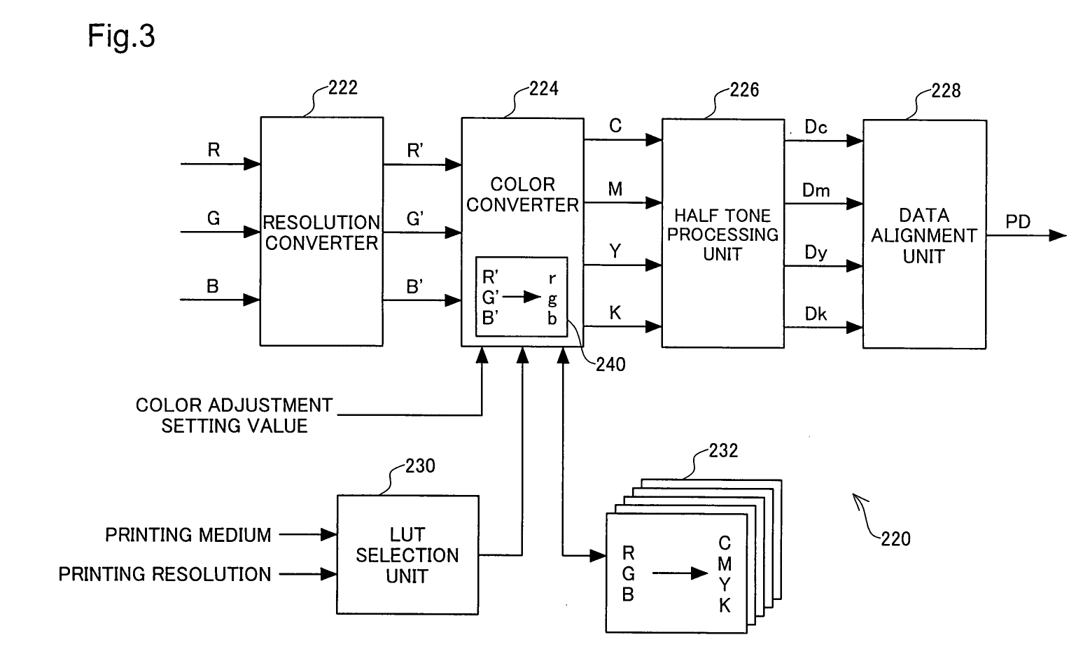

FIG. 3 is a block diagram that shows the arrangement of the printing data generating unit 220 in the first embodiment. The printing data generating unit 220 has a resolution converter 222, a color converter 224, a half tone processing unit 226, a data alignment unit 228, a lookup table selection unit 230, and a plurality of color conversion lookup tables 232.

The resolution converter 222 converts the resolution of the input RGB image data R, G, and B to printing resolution. The printing resolution image data R′, G′, and B′ output from the resolution converter 222 is image data for which each pixel color is represented by RGB values. In other words, the printing resolution image data R′, G′, and B′ is an image data represented by the RGB color system.

The color converter 224 has a color adjustment unit 240. Color adjustment setting values determined according to each type of parameter stored in the control execution unit 200 (FIG. 1) is supplied to the color adjustment unit 240. When the “COPY” mode is set to “CLEAR TEXT” mode as shown in the example of FIG. 2C, the color adjustment unit 240 generates internal image data rgb from the printing resolution image data R′G′B′ based on the supplied color adjustment setting values. The conversion from the printing resolution image data R′G′B′ to the internal image data rgb by color adjustment will be described later. Meanwhile, when the “COPY” mode is set to the “PHOTO” mode for more accurate reproduction of the original color, color adjustment by the color adjustment unit 240 is not performed.

The color converter 224 converts the internal image data rgb to the ink amount data CMYK using one among of color conversion lookup tables 232. The series of processes performed by this color converter 224 corresponds to the process of converting the printing resolution image data R′G′B′ or rgb represented by the RGB color system to the image data CMYK represented by the CMYK color system.

The plurality of color conversion lookup tables 232 used respectively for the plurality of printing modes are stored in the ROM that the control execution unit 200 (FIG. 1) has. The lookup table selection unit 230 selects one lookup table, which is suitable for the printing mode to be actually used for printing, from among these plurality of color conversion lookup tables 232. The color converter 224 executes color conversion using this selected lookup table. In this embodiment, the color conversion lookup table 232 is selected according to the two parameters, one is the printing medium and another is the printing resolution.

The selected color conversion lookup table 232 outputs ink amounts CMYK corresponding to the input point which is specific values of the RGB values input to the color converter 224. The color converter 224 outputs the ink amount CMYK from the RGB value by performing interpolation as necessary on the input RGB values. The input points of the color conversion lookup table 232 are often set at fixed intervals in the range of each RGB component value, and such an input point is also called a grid point.

The half tone processing unit 226 generates the dot formation data Dc, Dm, Dy, and Dk that show the dot formation state for each printing pixel by executing half tone processing for each ink. The data alignment unit 228 aligns these dot formation data Dc, Dm, Dy, and Dk and outputs them as printing data PD.

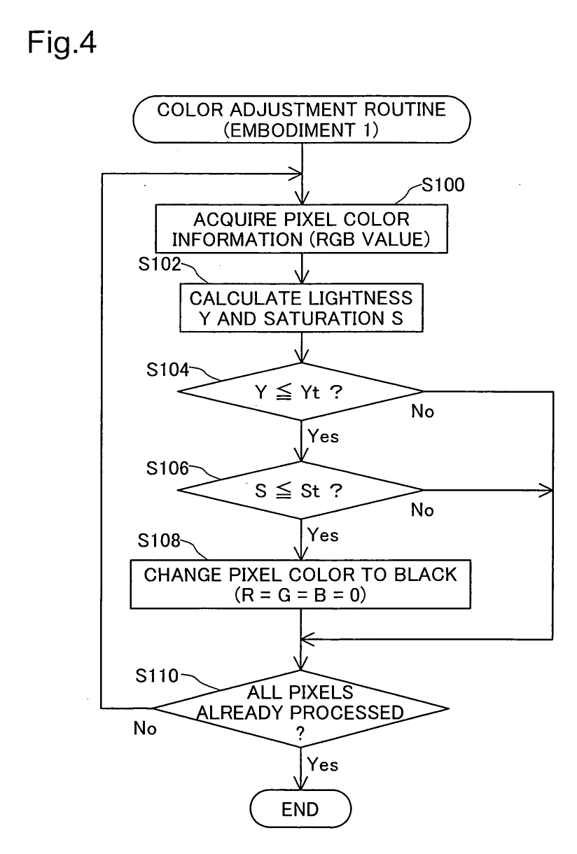

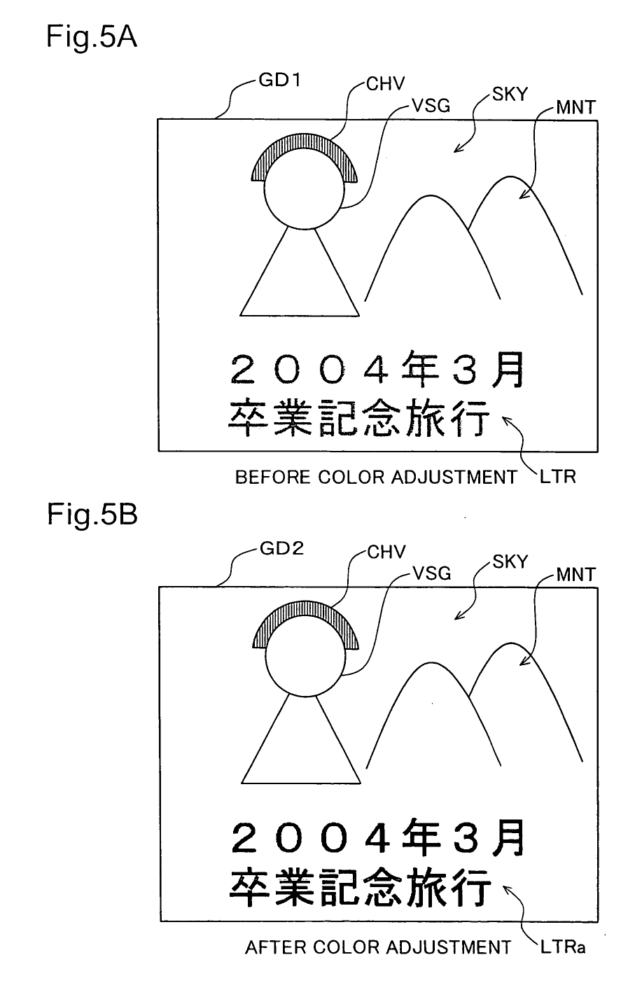

FIG. 4 is a flowchart of the procedure for generating the internal image data rgb by the color adjustment unit 240. FIGS. 5A and 5B illustrate the results of the color adjustment process. With the routine of FIG. 4, each pixel of the printing resolution image data R′G′B′ is analyzed in sequence (hereafter, the pixel subject to analysis at this time is called “the target pixel”), and the internal image data rgb is generated by adjusting the color of the target pixel.

FIG. 5A shows the printing resolution image data GD1 supplied to the color adjustment unit 240. This image data GD1 is the printing resolution image data generated by the scanner 110 reading an original that contains black colored text (illustrated as the text LTR of the image data GD1) and a photograph. In the photograph part of the image data GD1 includes a person's image constructed from the hair CHV and the face VSG as well as images of a sky SKY and mountain MNT that provide a backdrop for the person.

At step S100, the color adjustment unit 240 acquires the RGB values as the color information of the target pixel. At step S102, the color adjustment unit 240 calculates the lightness Y and the saturation S from the acquired RGB values. The lightness Y may be obtained using the following equation (1), and the saturation S may be obtained using the following equations (2) to (4), for example.
Y=0.30×R+0.59×G+0.11×B (1)
C₁0.7×R−0.59×G−0.11×B (2)
C_{M}=−0.3×R−0.59×G+0.89×B (3)
S=(C₁²+C₂²)^{1/2} (4)

In this embodiment, the lightness Y and the saturation S are obtained by a calculation according to the equations (1) through (4), but instead of this, it is also possible to obtain these values Y and S by using a table that has the lightness Y and the saturation S corresponding to the RGB values.

At step S104, the color adjustment unit 240 determines whether the lightness Y of the target pixel is the same or lower than the lightness threshold Yt which is one parameter of the color adjustment setting values. When the lightness Y of the target pixel is the same or lower than the lightness threshold Yt, the control moves to step S106. Meanwhile, when the lightness Y of the target pixel is greater than the lightness threshold Yt, the control moves to step S110, and the color of the target pixel is not changed. With the image data GD1 in the example of FIG. 5A, the face VSG which is the flesh color area and the sky SKY which is the light blue color area have lightness Y greater than the lightness threshold Yt, so the color is not changed.

At step S106, the color adjustment unit 240 determines whether the saturation S of the target pixel is the same or less than the saturation threshold St which is one parameter of the color adjustment setting values. When the saturation S of the target pixel is the same or less than the saturation threshold St, the control moves to step S108. Meanwhile, when the saturation S of the target pixel is greater than the saturation threshold St, the control moves to step S110, so the color of the target pixel is not changed. With the image data GD1 in the example of FIG. 5, the hair CHV which is the dark brown color area and the mountain MNT which is the dark green color area have saturation S that is greater than the saturation threshold St, so the color is not changed.

This lightness threshold Yt and saturation threshold St can be determined based on the RGB image data acquired by the image data acquisition unit 210 from a black color test chart as the original (hereafter, such a RGB image data is called “black image data”). In specific terms, the lightness and the saturation, which are respectively slightly larger values than the black color lightness Yb and the black color saturation Sb calculated from the RGB values of the black image data, can be used as the lightness threshold Yt and the saturation threshold St. As the lightness threshold Yt, for example, a value that is 5% greater than the black color lightness Yb is set (Yt=1.05×Yb). Also, as the saturation threshold St, for example, a value that is 5% greater than the black color saturation Sb is set (St=1.05×Sb).

The lightness threshold Yt and the saturation threshold St thus obtained can be stored in the ROM or non-volatile RAM incorporated in the control execution unit 200 and retrieved as necessary. It is also possible for the user to set these values by using a test chart as necessary.

At step S108, the color adjustment unit 240 changes the color of the target pixel to black color (R=G=B=0) by rewriting each of the three color component values of RGB to 0. In the example of FIGS. 5A and 5B, the color of the text LTR in the image data GD1 for which both of the lightness Y and the saturation S are smaller than the predetermined thresholds Yt and St is changed to black, and this becomes black text LTRa in the image data GD2.

At step S110, the color adjustment unit 240 determines whether the color adjustment process for all the pixels of the printing resolution image data R′G′B′ is completed. When color adjustment is completed for all the pixels, this color adjustment routine is ended. Meanwhile, when there are pixels for which color adjustment processing has not been performed, the target pixel is set to an unprocessed pixel, and the control returns to step S100. Then, the color adjustment unit 240 repeats execution of step S100 to S110 until color adjustment is completed for all the pixels.

By configuring the color converter 224 in this way, the input values in the RGB color system of colors close to black (hereinafter such a color is called as “neighborhood color of black” or “black neighborhood color”) are changed to the input value of black (R=G=B=0) within the color converter 224. Because of this, the color component value for the CMYK color system output from the color converter 224 has the same value for black and neighborhood colors of black. This black color is 0 for all the color component values C, M, and Y with the CMYK color system corresponding to the ink amount, and the color component value K becomes the maximum value (100%). Following, black in this kind of situation is also called the “color of ink K” or the “ink color K.” Other inks are called in the same way.

In the first embodiment, the ink dots that correspond to pixels of the ink color K of the printing resolution image data R′G′B′ and of the neighborhood colors of the ink color K are formed with the maximum amount of black ink (K). On the other hand, colors that are not neighborhood colors of the ink color K are not modified by the color adjustment. With the first embodiment, as shown in FIG. 5B, when photographs and text of ink color K are mixed in the input image, it is possible to reduce changing of the photograph color while outputting the text color as black. Because of this, the quality of the image part of the ink color K is improved when an input image that contains text of the ink color K is printed.

Also, with the color converter 224 in the first embodiment, the color adjustment unit 240 performs the color adjustment. As a result, the same color conversion lookup table 232 can be used for the mode performing the color adjustment (“CLEAR TEXT” mode) and the mode not performing the color adjustment (“PHOTO” mode). Because of this, it is not necessary to prepare a plurality of color conversion lookup tables 232 for each mode, so it is possible to reduce the capacity of the storage devices incorporated in the SPC complex 100.

B. Embodiment 2:

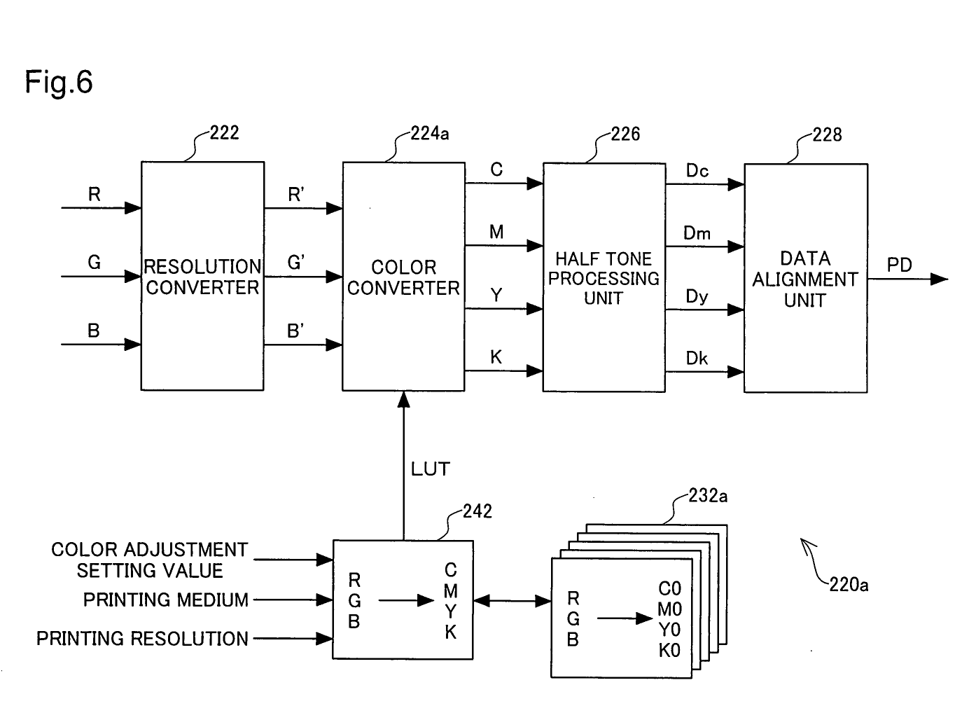

FIG. 6 is a block diagram that shows the arrangement of the printing data generating unit 220a in the second embodiment. The printing data generating unit 220a of the second embodiment differs from the first embodiment in that it has a lookup table generating unit 242 in place of the lookup table selection unit 230 (FIG. 3) and the color adjustment unit 240 (FIG. 3). The lookup table generating unit 242 selects one lookup table, which is suitable for the printing mode actually used for printing, from among the plurality of color conversion source lookup table 232a. The lookup table generating unit 242 generates a color conversion lookup table LUT supplied to the color converter 224a from the selected color conversion source lookup table. The generation of the color conversion lookup table LUT will be described later. The color converter 224a converts the printing resolution image data R′G′B′ to the ink amount data CMYK using the color conversion lookup table LUT generated by the lookup table generating unit 242. The other arrangements and functions are almost the same as those of the first embodiment.

As shown in FIG. 2C, the generation of the color conversion lookup table LUT by the lookup table generating unit 242 is executed when the setting value of the “COPY” mode is changed to the “CLEAR TEXT” mode. Meanwhile, when the setting value of the “COPY” mode is not changed and it is left as the “PHOTO” mode, the color converter 224a converts the printing resolution image data R′G′B′ to the ink amount data CMYK using one table selected from among the plurality of color conversion source lookup tables 232a.

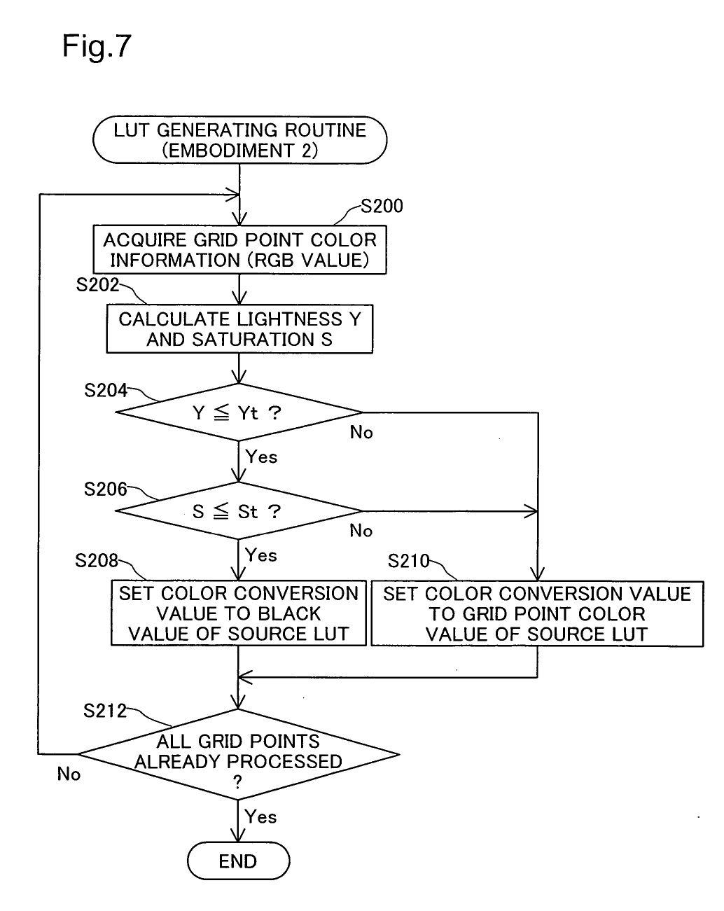

FIG. 7 is a flowchart of the procedure for generation of a color conversion lookup table LUT by the lookup table generating unit 242 in the second embodiment. With the routine of FIG. 7, each grid point of the color conversion lookup table LUT is analyzed in sequence (hereafter, the grid point subject to analysis at this time are called a “target grid point”). The ink amount data (hereafter, also called “color conversion value”) for the target grid point is determined according to the color conversion source lookup table 232a and the color adjustment setting value. In the second embodiment, a different color conversion value is set for each grid point of the color conversion source lookup table 232a.

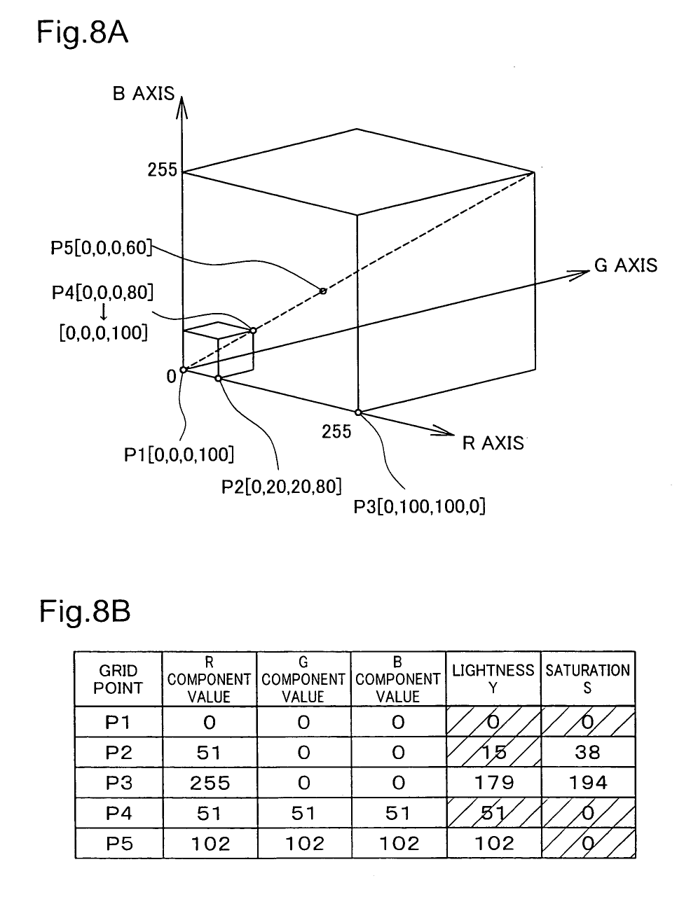

FIG. 8A illustrates the results of the process of generating the color conversion lookup table LUT in the second embodiment. Numerical values in the square brackets attached to grid points P1 to P5 show the color conversion values C0, M0, Y0, and K0 which are the color conversion values corresponding to each grid point P1 to P5 determined by using the color conversion source lookup table 232a. FIG. 8B is a table that shows the RGB values and lightness Y and saturations S of each of the grid points P1 to P5 shown in FIG. 8A. The shaded parts of FIG. 8B indicate that the lightness Y and the saturation S are respectively the same or less than the lightness threshold Yt (with this embodiment, we will explain as Yt=51) and the saturation threshold St (with this embodiment, we will explain as St=32).

At step S200, the lookup table generating unit 242 acquires the RGB values as the color information of the target grid point. At step S202, the lookup table generating unit 242 calculates the lightness Y and the saturation S from the acquired RGB values. The lightness Y and the saturation S may be calculated in the same way as with the first embodiment.

At step S204, the lookup table generating unit 242 determines whether the lightness Y of the target grid point is the same or less than the lightness threshold Yt which is one parameter of the color adjustment setting values. When the lightness Y of the target grid point is the same or less than the lightness threshold Yt, the control moves to step S206. Meanwhile, when the lightness Y of the target grid point is greater than the lightness threshold Yt, the control moves to step S210. In the example of FIG. 8A, with the target grid points such as grid points P1, P2, and P4 for which the lightness Y is smaller than the lightness threshold Yt, the control moves to step S206. Meanwhile, with the target grid points such as grid points P3 and P5 for which the lightness Y is greater than the lightness threshold Yt, the control moves to step S210.

At step S206, the lookup table generating unit 242 determines whether the saturation S of the target grid point is the same or less than the saturation threshold St which is one parameter of the color adjustment setting values. When the saturation S of the target grid point is the same or less than the saturation threshold St, the control moves to step S208. Meanwhile, when the saturation S of the target grid point is greater than the saturation threshold St, the control moves to step S210. In the example of FIG. 8A, with the target grid point such as grid points P1 and P4 for which the saturation S is less than the saturation threshold St, the control moves to step S206. Meanwhile, with the target grid point such as a grid point P2 for which the saturation S is greater than the saturation threshold St, the control moves to step S210.

At step S208, the lookup table generating unit 242 sets the color conversion values C, M, Y, and K of the target grid points to the black color conversion value of the color conversion source lookup table 232a (C=M=Y=0, K=100). Meanwhile, at step S210, the lookup table generating unit 242 sets the color conversion values C, M, Y, and K of the target grid points to the color conversion values C0, M0, Y0, and K0 of the color conversion source lookup table 232a corresponding to the target grid points. In this way, the generated color conversion lookup table LUT becomes a table for which, of the color conversion values of the color conversion source lookup table 232a, the color conversion values of the black neighborhood colors are replaced with the black color conversion values. In the example of FIG. 8A, the color conversion values C, M, Y, and K of the grid points P1 and P4 are set to the black color conversion values (C=M=Y=0, K=100), and the color conversion values of the other grid points P2, P3, and P5 are set to the color conversion values C0, M0, Y0, and K0 of the color conversion source lookup table 232a.

At step S212, the lookup table generating unit 242 determines whether the setting of the color conversion values of all the grid points is complete. When it is determined that the setting of the color conversion values of all the grid points is complete, this lookup table generating routine ends. Meanwhile, when there are grid points for which setting of the color conversion values has not been performed, the target grid point is set to an unprocessed grid point, and the control returns to step S200. Then, the lookup table generating unit 242 repeats execution of the steps S200 to S212 until the setting of color conversion values for all the grid points is completed.

In this way, the lookup table generating unit 242 in the second embodiment generates a color conversion lookup table LUT that outputs the same output values for black and for the grid points of the black neighborhood colors. Thus the color conversion unit 224a outputs the same output value that corresponds to the black input value for the black color (ink color K) and the black neighborhood color input values by using the generated color conversion lookup table LUT.

In the second embodiment as well, the same as with the first embodiment, the ink color K and neighborhood colors of ink color K are output as maximum amount black ink (K), and colors that are not neighborhood colors of ink color K are output as suitable colors. Because of this, with the second embodiment as well, when a photograph and ink color K text are mixed in an input image, it is possible to reduce changes in the photograph colors while outputting the text color as black, so the quality of the ink color K image part is improved. Also, in the-second embodiment as well, it is possible to use the same color conversion source lookup table 232a with a plurality of modes, so it is possible to reduce the storage capacity required for keeping the color conversion source lookup table 232a.

With the second embodiment, a color adjustment process is not performed for each pixel. As a result, it is possible to reduce the time required for processing for improving the quality of the output image. Because of this, the second embodiment is preferable compared to the first embodiment. Meanwhile, the first embodiment is preferable compared to the second embodiment in that any value that is suitable for improving the quality of the output image can be used for the lightness threshold Yt and the saturation threshold St.

C. Embodiment 3:

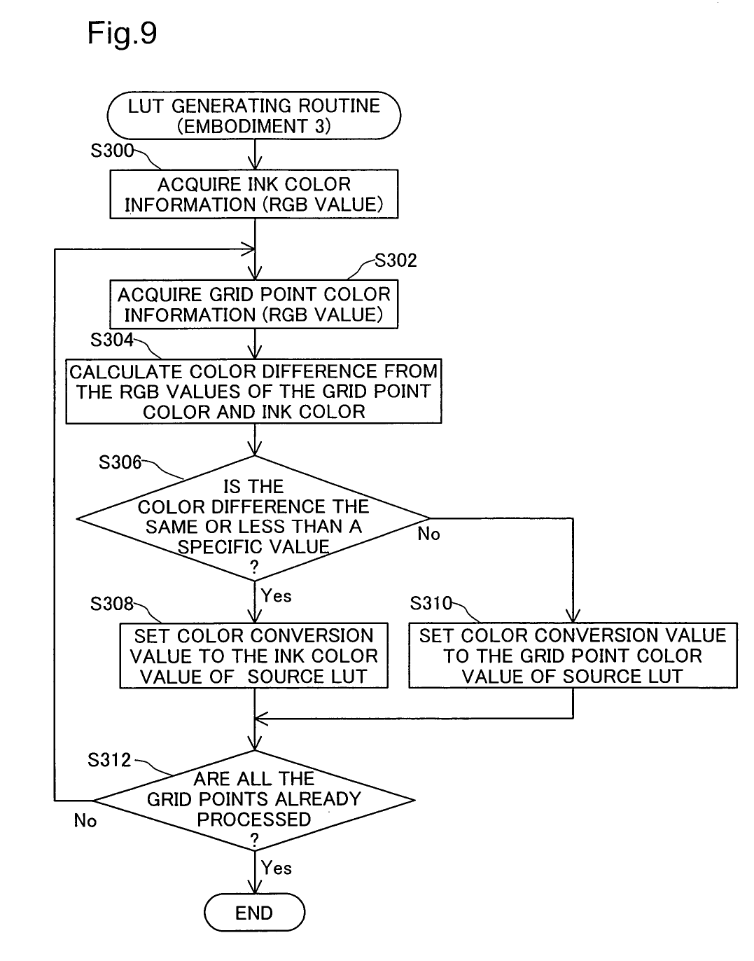

FIG. 9 is a flowchart of the procedure for generation of a color conversion lookup table by the lookup table generation unit 242 in the third embodiment. The routine of FIG. 9 differs from that of the second embodiment in that the ink color Y color conversion value is set for the grid point of the ink color Y neighborhood color. The other arrangements and functions are almost the same as those of the second embodiment.

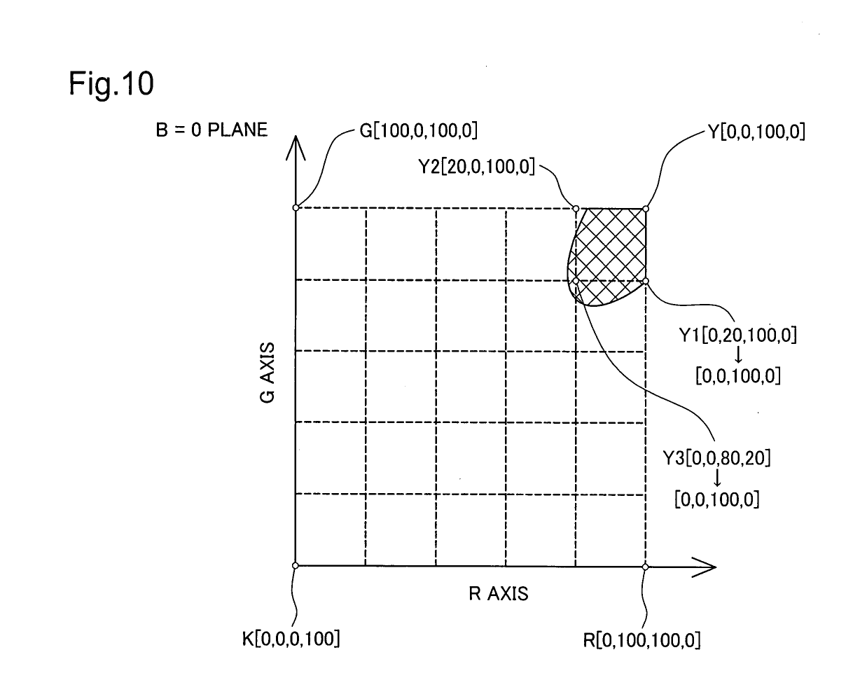

FIG. 10 illustrates the results of the process of generating the color conversion lookup table LUT in the third embodiment. The numerical values in the square brackets attached to grid points Y, Y1 to Y3, and R, G, and K show the color conversion values C0, M0, Y0, and K0 when the colors of each grid point Y, Y1 to Y3, and R, G, and K are converted using the color conversion source lookup table 232a. The cross hatched part of FIG. 10 shows a color area for which color difference ΔE (to be described later) to the ink color Y is the same or less than a predetermined color difference threshold δ. The color conversion lookup table LUT for which the RGB color system color is the input value is a three dimensional space that has each of the RGB color components as a coordinate axis, but to make illustration easier, FIG. 10 shows an R-G plane with a color component B=0.

At step S300, the lookup table generating unit 242 acquires the RGB value as the color information of the ink color Y. In specific terms, the lookup table generating unit 242 acquires the RGB value of the ink color Y by referencing the correspondence table of the ink color and the RGB value. The ink color Y RGB value can be acquired not only by referencing the table as described in this embodiment, but also can be acquired by obtaining the color conversion value according to the color conversion source lookup table 232a for each grid point, and obtaining the respective grid points for which the Y component is the maximum and each CMK component is 0.

At step S302, the lookup table generating unit 242 acquires the RGB value as the color information of the target grid point. At step S304, the lookup table generating unit 242 calculates the color difference between the color of the target grid point and the ink color Y. For the color difference between the color of the target grid point and the ink color Y, it is possible to use the color difference ΔE in the L*a*b* color system, for example. For the color difference between the color of the target grid point and the ink color Y, it is also possible to use a color difference in another color system such as the L*u*v* color system as long as it is possible to determine if the color of the target grid point is a neighborhood color of the ink color Y.

At step S306, the lookup table generating unit 242 determines whether the color difference ΔE between the color of the target grid point and the ink color Y is the same or less than the color difference threshold δ which is one parameter of the color adjustment setting values. When the color difference ΔE between the color of the target grid point and the ink color Y is the same or less than the color difference threshold δ, the control moves to step S308. Meanwhile, when the color difference ΔE between the color of the target grid point and the ink color Y is greater than the color difference threshold δ, the control moves to step S310. In the example of FIG. 10, with grid points Y, Y1, and Y3 for which the color difference ΔE with the ink color Y is smaller than the color difference threshold δ, the control moves to step S308. Meanwhile, with the grid point Y2, R, G, and K for which the color difference ΔE with the ink color Y is greater than the color difference threshold δ, the control moves to step S310.

The color difference threshold δ can be determined based on the RGB image data (yellow image data) acquired by the image data acquisition unit 210 (FIG. 1) from a yellow (ink color Y) test chart as the original. In specific terms, the yellow color difference ΔEy is calculated from the respective RGB values of the yellow image data and the ink color Y, and a value that is slightly larger than the yellow color difference ΔEy can be set as the color difference threshold δ. As the color difference threshold δ, it is also possible to set a value that is 5% greater than the yellow color difference ΔEy (δ=1.05×ΔEy), for example.

At step S308, the lookup table generating unit 242 sets the color conversion values C, M, Y, and K of the target grid points to the ink color Y color conversion value (C=M=K=0, Y=100) according to the color conversion source lookup table 232a. Meanwhile, at step S310, the lookup table generating unit 242 sets the color conversion values C, M, Y, and K of the target grid points to the color conversion values C0, M0, Y0, and K0 of the color conversion source lookup table 232a. In the example of FIG. 10 (a), the color conversion values C, M, Y, and K of the grid points Y, Y1, and Y3 are set to the ink color Y color conversion values (C=M=K=0, Y=100), and the color conversion values of the other grid points Y2, R, G, and K are set to the color conversion values C0, M0, Y0, and K0 of the color conversion source lookup table 232a.

At step S312, the lookup table generating unit 242 determines whether setting of the color conversion values for all the grid points is completed. When it is determined that setting of the color conversion values of all the grid points is completed, this lookup table generating routine ends. Meanwhile, when there are grid points for which color conversion values have not been set, the target grid point is set to an unprocessed grid point, and the control returns to step S302. Thus, the lookup table generating unit 242 repeats execution of steps S302 to S312 until setting of the color conversion values is completed for all the grid points.

In this way, the lookup table generating unit 242 in the third embodiment generates a color conversion lookup table LUT that outputs the same output value for the ink color Y and for the grid points of the ink color Y neighborhood colors. Thus, the color conversion unit 224a outputs the same output value corresponding to the input value of the ink color Y in relation to the input value of the ink color Y and the ink color Y neighborhood colors by using the generated color conversion lookup table LUT.

In this embodiment, the procedure for generating a color conversion lookup table LUT that outputs the same output value to the ink color Y and the ink color Y neighborhood color input values is explained. But by performing the same process on other ink colors C, M, and K as well, it is possible to generate a color conversion lookup table LUT that outputs the same output value to the input value of one or more of any ink color and that ink color neighborhood color. In this case, it is possible to use a different color difference threshold δ for each different ink color.

In the third embodiment as well, the same as with the first embodiment, the ink color and ink color neighborhood colors are output with the maximum amount of ink, and colors that are not the ink color neighborhood colors are output as suitable colors. Because of this, with the third embodiment as well, when a photograph and single color image with color closed to the ink color are mixed in the input image, it is possible to reduce changes in the photograph color while outputting the single color image with the ink color, so the quality of the ink color image part is improved. Also, with the third embodiment as well, it is possible to use the same color conversion source lookup table 232a with a plurality of modes, so it is possible to reduce the recording capacity required for holding the color conversion source lookup table 232a.

The third embodiment is preferable compared to the first and second embodiments because it is able to improve the output image quality for input image that contains single color image with color closed to any ink color. On the other hand, the second embodiment is preferable to the third embodiment in terms of it being easy to generate a color conversion lookup table LUT. Also, the first embodiment is preferable to the third embodiment in terms of it being possible to use any value suitable for improvement of the quality of the output image for the lightness threshold Yt and the saturation threshold St.

In the third embodiment, the lookup table generating unit 242 generates a color conversion lookup table LUT that outputs the same output value in relation to the ink color and the ink color neighborhood color input values, but it is also possible to generate a color conversion lookup table LUT that outputs the same output value in relation to a specific color and its neighborhood color input values. In this case, when the color difference ΔE between the color of the target grid point and the specific color is the same or less than the color difference threshold δ, a color conversion value is set for which the specific color of the target grid point is converted by the color conversion source lookup table 232a, and when the color difference ΔE between the color of the target grid point and the specific color is greater than the color difference threshold δ, it is possible to have a color conversion value set for which the color of the target grid point is converted by the color conversion source lookup table 232a for the target grid point.

D. Embodiment 4:

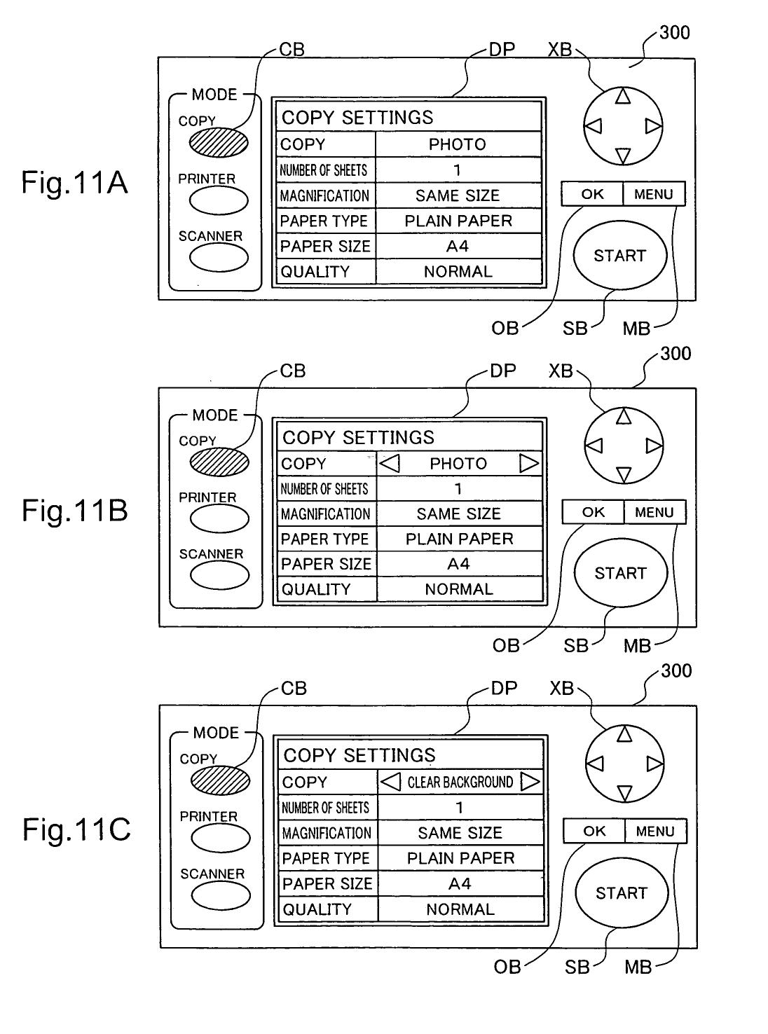

FIGS. 11A to 11C illustrate the operating panel 300 during the settings of the SPC complex 100 (FIG. 1) in the fourth embodiment. The fourth embodiment differs from the first embodiment in that the “COPY” mode setting value is set to the “CLEAR BACKGROUND” mode instead of the “CLEAR TEXT” mode and the color adjustment unit 240 (FIG. 3) executes the different procedure according to the difference of the “COPY” mode. The other arrangements and functions are almost the same as those of the first embodiment.

FIG. 11A and FIG. 11B show the operating panel 300 when the user selects the copy mode as the operating mode of the SPC complex 100 and the setting item to change to the “COPY” mode. FIG. 11A and FIG. 11B are identical to FIG. 2A and FIG. 2B of the first embodiment respectively, description thereof will be omitted.

FIG. 11C shows the operating panel 300 when the setting value of the “COPY” mode is changed from the “PHOTO” mode to the “CLEAR BACKGROUND” mode. In the example of FIG. 11C, the “COPY” mode setting value is changed from the “PHOTO” mode to the “CLEAR BACKGROUND” mode. The changed setting values are supplied to the control execution unit 200 (FIG. 1) and the control execution unit 200 stores the supplied setting values in a temporary storage device as in the first embodiment.

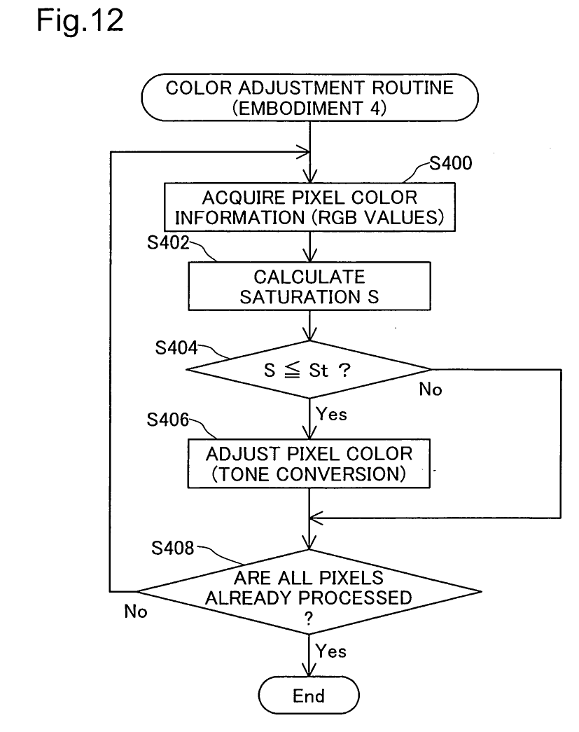

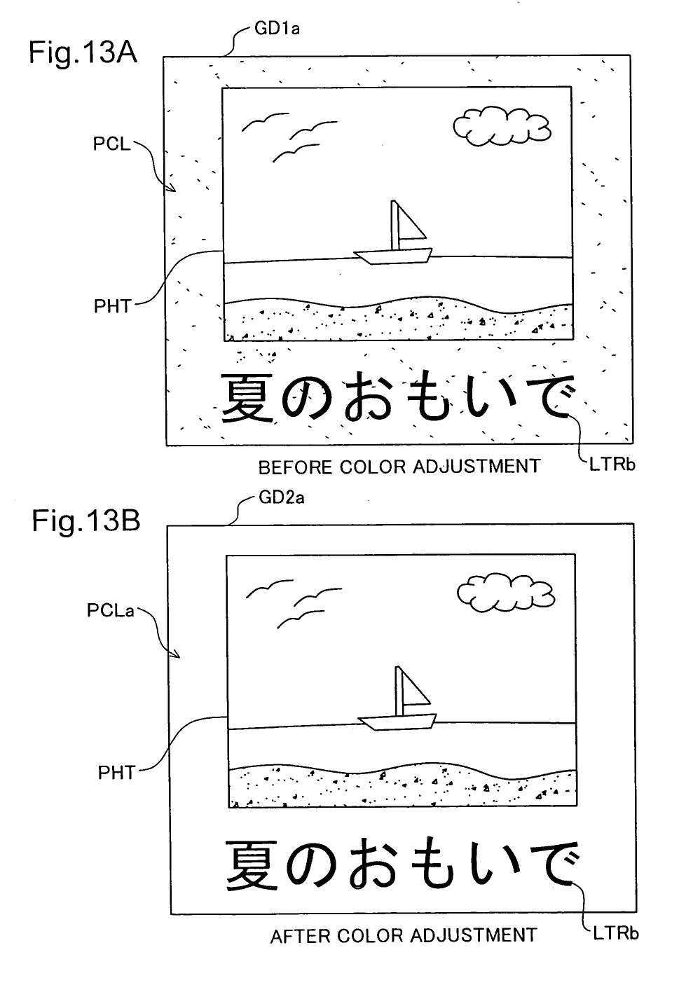

FIG. 12 is a flowchart of the procedure for generating the internal image data rgb by the color adjustment unit 240 (FIG. 3) in the fourth embodiment. FIGS. 13A and 13B illustrate the results of the color adjustment process.

FIG. 13A shows the print resolution image data GD1a that is supplied to the color adjustment unit 240. This image data GD1a is print resolution image data that is generated by the scanner 110 reading an original that contains black text (illustrated as the black text LTRb of the image data GD1a) and a photograph (illustrated as the photograph PHT of the image data GD1a). In addition to the black text LTR and photograph PHT that are images contained in the original, a background noise image PCL that shows the paper color (background color) is also included in the image data GD1a.

At step S400, the color adjustment unit 240 acquires the RGB values as the color information of the target pixel. At step S402, the color adjustment unit 240 calculates the saturation S from the acquired RGB values. The saturation S may be calculated in the same way as with the first embodiment by the equations (2) through (4) described above.

At step S404, the color adjustment unit 240 determines whether the saturation S of the target pixel is the same or less than a predetermined saturation threshold St. When the saturation S of the target pixel is the same or less than the saturation threshold St, specifically, when the color of the target pixel is a color in a predetermined range that includes achromatic colors, the control moves to step S106. Meanwhile, when the saturation S of the target pixel is greater than the saturation threshold St, the control moves to step S108, so the color of the target pixel is not changed. In the example of FIGS. 13A and 13B, PHT, which is the photograph area of the image data GD1a having a saturation S greater than the saturation threshold St, the color does not change.

This saturation threshold St can be determined, for example, based on the RGB image data acquired by the image data acquisition unit 210 by reading a test chart, which has an area of a different color such as a color sample, as the original (hereafter, such a RGB image data is called “color sample image data”). In specific terms, the saturation S calculated from the RGB values in the color area, of which change of the hue occurred by tone conversion (to be described later) of the color sample image is allowable, can be used as the saturation threshold St.

The saturation threshold St thus obtained can be stored in the ROM or non-volatile RAM incorporated in the control execution unit 200 and retrieved as necessary. It is also possible for the user to set the value by using a test chart as necessary.

At step S406, the color adjustment unit 240 performs color adjustment on the target pixel by respectively rewriting the three color component values of RGB of the target pixel. The color adjustment of the target pixel is performed by the color adjustment unit 240 doing tone conversion that modifies each RGB color component value according to the tone conversion characteristics (tone curve).

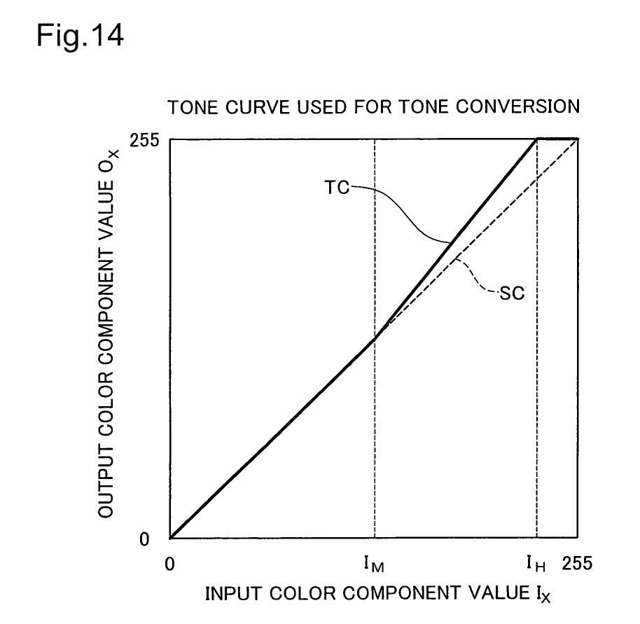

FIG. 14 shows the tone curve TC that is used for color adjustment of the target pixel in the fourth embodiment. The horizontal axis in FIG. 14 shows the color component input value (input color component value I_{X}), and the vertical axis in FIG. 14 shows the color component output value when tone conversion is performed on the input color component value I_{X} (output color component value O_{X}). This tone curve TC is expressed by the following equations (5) through (7) using the middle reference value I_{M} and the highlight reference value I_{H}. Note that the dotted line SC of FIG. 14 shows a reference tone curve when color adjustment is not performed (O_{X}=I_{X}).
O_{X}=I_{X} 0≦I_{X}<I_{M} (5)
O_{X}=Δ(I_{X}−I_{M})+I_{M} I_{M}≦I_{X}<I_{H} (6)
where Δ=(255−I_{M})/(I_{H}−I_{M})
O_{X}255 I_{H}≦I_{X}≦255 (7)

In this way, with the tone curve TC, when the input color component value I_{X} is smaller than the middle reference value I_{M}, the same value as the input color component value I_{X} (O_{X}=I_{X}) is output as the output color component value O_{X}. Meanwhile, when the input color component value I_{X} is in a range between the medium reference value I_{M} and the highlight reference value I_{H}, the tone curve slope Δ is greater than 1, so a value that is greater than the input color component value I_{X} is output as the output color component value O_{X}. When the input color component value I_{X} is the same or greater than the highlight reference value I_{H}, the maximum value (255) of the output color component value O_{X} is output as the output color component value O_{X}.

The tone curve TC of FIG. 14 is depicted with the middle reference value I_{M} as 127 and the highlight reference value I_{H} as 230, but it is also possible to set this middle reference value I_{M} and highlight reference value I_{H} as a suitable value for which the color of the background noise image PCL can be converted to white. This kind of middle reference value I_{M} and highlight reference value I_{H} can be determined based on the RGB image data (white paper image data) output by the image data acquisition unit 210 when white paper is read, for example. In specific terms, a value which is slightly smaller than the minimum value of the RGB value of the white paper image data is set for the highlight reference value I_{H}, and the middle reference value I_{M} is set so that the tone curve slope Δ does not exceed a predetermined value (e.g. 1.5).

The same as with the saturation threshold St, these reference values I_{M} and I_{H} thus obtained can be stored in the ROM or non-volatile RAM incorporated in the control execution unit 200 and retrieved as necessary. It is also possible to make it so that the user can change the settings of these reference values I_{M} and I_{H} as necessary.

When each of the RGB color component values of the target pixel is greater than the middle reference value I_{M} (lightness is high), by performing tone conversion using the tone curve TC, the color of the target pixel is changed to color with higher lightness. In particular, when each of the RGB color component values of the target pixel is respectively greater than the highlight reference value I_{H}, the color of the target pixel is changed to white (R=G=B=255). Meanwhile, when the lightness of the target pixel is low, the color component value of the target pixel does not change, so the color of the target pixel does not change. In this way, when the lightness of the color of the target pixel is higher than a predetermined threshold (R=G=B=I_{M}), the lightness of the color of the target pixel becomes higher with the tone conversion by the tone curve TC.

In the example of FIGS. 13A and 13B, of the image data GD1a images PCL and LTRb for which the saturation S is the same or lower than the saturation threshold St, the background noise image PCL becomes an image of high lightness. Because of this, the lightness of the background noise image PCL becomes higher by the color adjustment. The background noise image PCL is converted to the white image PCLa as shown in FIG. 13B because the highlight reference value I_{H} is set as described above. In contrast to this, color conversion is not performed for the black text LTRb because it has low lightness, and it is the same image LTRb as before and after the color adjustment.

At step S408, the color adjustment unit 240 determines whether the color adjustment process is completed for all the pixels of the print resolution image data R′G′B′. When it is determined that color adjustment is completed for all the pixels, this color adjustment routine ends. Meanwhile, when there are pixels for which color adjustment processing has not been performed, an unprocessed pixel is set to the target pixel, and the control returns to step S400. Then, the color adjustment unit 240 repeats execution of steps S400 to S408 until color adjustment is completed for all the pixels.

In this way, the color adjustment unit 240 does not change the color of pixels that, of the print resolution image data R′G′B′, are in areas with high saturation such as with photographs or of areas of low lightness such as with text. Because of this, these areas of the internal image data rgb are the same images as the print resolution image data R′G′B′. Meanwhile, areas of background color with low saturation and high lightness become white with the color adjustment, so images of the background color area do not appear in the internal image data rgb.

The color converter 224 of the fourth embodiment performs color conversion of the internal image data rgb that was generated by the color adjustment unit 240, so ink amount data CMYK that shows white color (C=M=Y=K=0) is output to the background color area of the print resolution image data R′G′B′. Meanwhile, the colors of areas such as photographs and text, etc. are not changed by the color adjustment unit 240, so ink amount data CMYK suitable for printing is output to these areas. Because of this, it is possible to output the paper color as a white color with an ink amount of 0 while reducing changes in color to photographs and text, so there is an improvement in the quality of output images when outputting input images that were generated by reading an original.

Also, with the color converter 224 of the first embodiment, it is possible to use the same color conversion lookup table 232 as the color conversion lookup table 232 used in modes for which color adjustment is not performed (“PHOTO” mode) with modes for which color adjustment is performed (“CLEAR BACKGROUND” mode). Because of this, it is not necessary to prepare a plurality of color conversion lookup tables 232 for each mode, so it is possible to reduce the capacity of the storage device incorporated in the SPC complex 100.

E. Embodiment 5:

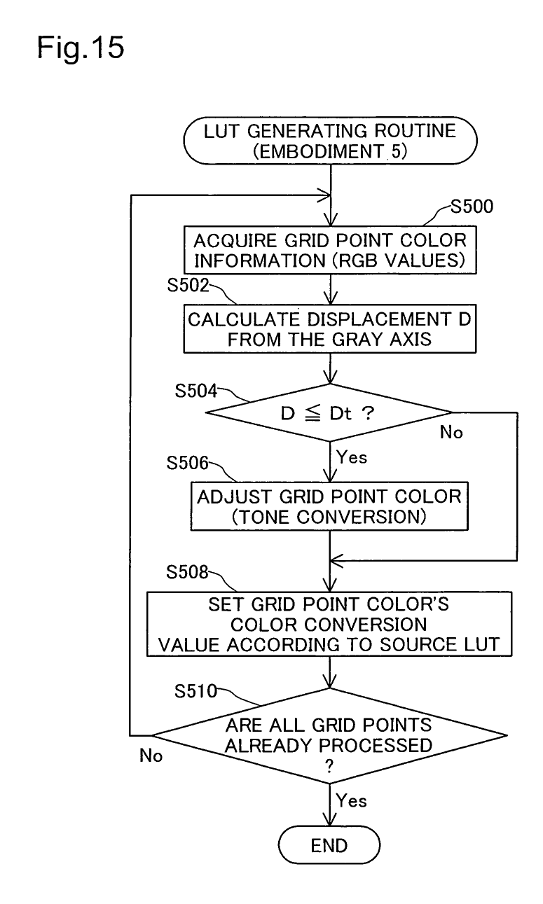

FIG. 15 is a flowchart of the procedure for generation of a color conversion lookup table LUT by the lookup table generating unit 242 in the fifth embodiment. The fifth embodiment differs from the second embodiment in that the “COPY” mode setting value is set to the “CLEAR BACKGROUND” mode instead of the “CLEAR TEXT” mode and the lookup table generating unit 242 (FIG. 6) executes the different procedure according to the difference of the “COPY” mode. The other arrangements and functions are almost the same as those of the second embodiment.

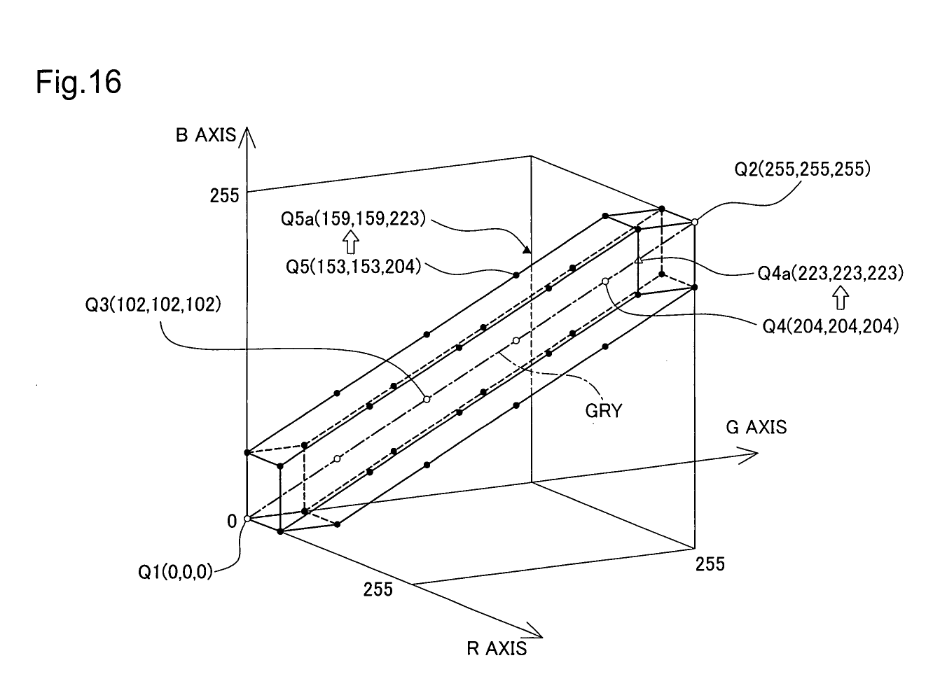

FIG. 16 illustrates the result of the process of generating a color conversion lookup table LUT in the fifth embodiment. Numerical values in the parentheses attached to the grid points Q1 to Q5 show the color component values in the RGB color system of each grid point Q1 to Q5.

At step S500, the lookup table generating unit 242 acquires the RGB values that are the color information of the target grid points. At step S502, the lookup table generating unit 242 calculates the displacement D, which indicates the distance between the target grid point and the gray axis GRY representing the achromatic colors, from the acquired RGB values R, G, and B. For example, the displacement D can be calculated by the following equation (8) using the RGB values R, G, and B of the target grid point and the RGB values R₀, G₀, and B₀ of the grid point on the gray axis GRY closest to the target grid point.
D=max(|R−R₀|, |G−G₀|, |B−B₀|) (8)

At step S504, the lookup table generating unit 242 determines whether the displacement D of the target grid point is the same or less than a predetermined displacement threshold Dt. When the displacement D of the target grid point is the same or less than the displacement threshold Dt, specifically, when the color of the target grid point is a color within a predetermined range that includes achromatic colors, the control moves to step S206. Meanwhile, when the displacement D of the target grid point is greater than the displacement threshold Dt, the control moves to step S208. In the example of FIG. 16, the grid points shown by circles are grid points for which the displacement D is the same or less than the displacement threshold Dt. Of these circles, the white circles show grid points on the gray axis GRY, and the black circles show grid points outside the gray axis GRY.

The predetermined displacement threshold Dt can be set, for example, as a displacement D calculated from the RGB values of the grid point adjacent to the gray axis GRY. It is also possible to use the saturation S of the fourth embodiment as the displacement D and to set the displacement threshold Dt as the saturation threshold St of the fourth embodiment.

At step S506, the lookup table generating unit 242 performs tone conversion the same way as with the fourth embodiment on each RGB component value of the target grid point. In the example of FIG. 16, each RGB component value of the grid points Q4 and Q5 take values between the middle reference value I_{M} (FIG. 14) and the highlight reference value I_{H} (FIG. 14), so each RGB component value is changed by tone conversion. Because of this, each RGB component value of the points Q4a and Q5a is used for setting the color conversion values of the grid points Q4 and Q5. Meanwhile, each RGB component value is not changed even by tone conversion for the grid points Q1, Q2, and Q3, so for the setting of the color conversion values of the grid points Q1, Q2, and Q3, each RGB component value of the grid points Q1, Q2, and Q3 is used as is.

At step S508, the lookup table generating unit 242 sets color conversion values that correspond to each RGB component value after the tone conversion for the target grid point. For the target grid points for which the displacement D is greater than the displacement threshold Dt or the target grid points for which each RGB component value is not changed by the tone conversion, the color conversion values C0, M0, Y0, and K0 of the color conversion source lookup table 232a are set as is. For the target grid points for which each RGB component value is changed by tone conversion, color conversion values CMYK that correspond to each changed RGB component value are set. In this case, the points shown by each changed RGB component value are away from the grid points, so the color conversion values CMYK are obtained by interpolation using the color conversion source lookup table 232a. In the example of FIG. 16, each RGB color component of the grid points Q4 and Q5 is changed by tone conversion, so color conversion values CMYK that correspond to the points Q4a and Q5a are set for the grid points Q4 and Q5. Meanwhile, each RGB component value of the grid points Q1, Q2, and Q3 are not changed by tone conversion, so they are set to the color conversion values C0, M0, Y0, and K0 of the color conversion source lookup table 232a.

In this way, the color conversion lookup table LUT, which is generated by the lookup table generating unit 242 of the fifth embodiment, outputs an modified output value representing a color with a higher lightness than the output value of the color conversion source lookup table 232a when an input value which represents a color of a predetermined range is input.

At step S210, the lookup table generating unit 242 determines whether the setting of the color conversion values is completed for all the grid points. When it is determined that setting of the color conversion values is completed for all the grid points, this lookup table generating routine ends. Meanwhile, when there are grid points for which color conversion value setting has not been performed, the target grid point is set to an unprocessed grid point, and the control returns to step S500. Then, the lookup table generating unit 242 repeats execution of steps S500 to S510 until setting of the color conversion values of all the grid points is completed.

When grid points near the gray axis GRY are input, the lookup table LUT of the fifth embodiment generated in this way outputs an output value that represents a color with a higher lightness when the color shown by the grid point has a high lightness. Then, when the lightness shown by the grid point near the gray axis GRY is the same or higher than a predetermined value, an output value that shows white (C=M=Y=K=0) is output. Because of this, as with the background color, when color conversion is performed using the color conversion lookup table LUT on a color for which the saturation is low and the lightness is high, the ink amount CMYK becomes almost 0.

For the fifth embodiment as well, as with the fourth embodiment, the background color is output as a white color of ink amount almost 0, and areas which are not the background color are output with suitable colors. Because of this, for the fifth embodiment as well, it is possible to output the paper color as white while reducing changes in the photograph and text colors, so there is improvement in the quality of the output image when the image output by reading the original is output. Also, for the fifth embodiment as well, it is possible to use the same color conversion source lookup table 232a with a plurality of modes, so it is possible to reduce the storage capacity required for keeping the color conversion source lookup table 232a.

The fifth embodiment does not perform color adjustment processing for each pixel, so it is preferable to the fourth embodiment in terms of being able to shorten the time required for processing to improve the quality of output images. Meanwhile, the fourth embodiment performs color adjustment for each pixel, so it is preferable to the fifth embodiment in terms of being able to have an ink amount value of 0 for the background color pixels.

With the fifth embodiment, the lightness of the color shown by the output value is increased by adjusting the output value set for the grid point, but it is also possible to increase the lightness of the color shown by the output value by adjusting the output value generated using the color conversion source lookup table 232a. For example, when the color shown by an input value is a color of a predetermined range that contains achromatic colors, it is also possible to reduce the output ink amount based on the predetermined conversion characteristics.

F. Variations of Tone Curve:

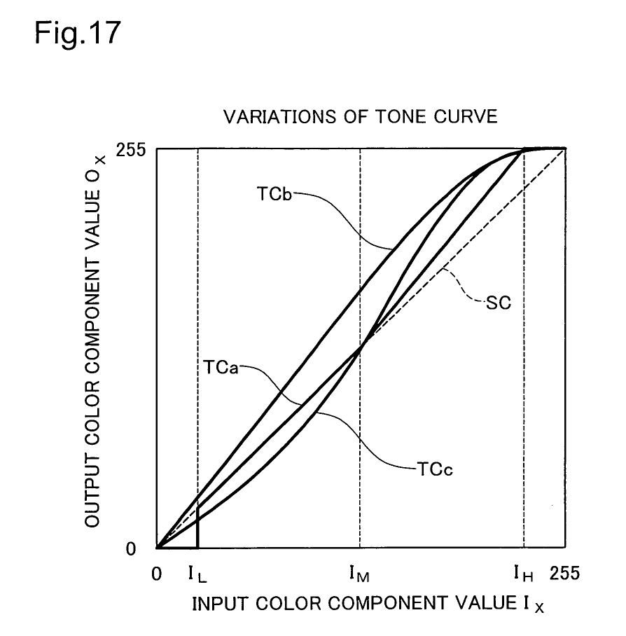

FIG. 17 shows variations of the tone curve used for the tone conversion. With the fourth and fifth embodiments, the tone conversion is performed using the tone curve TC shown in FIG. 14. But any tone curve which is able to output an output color component value O_{X} greater than the input color component value I_{X} is applicable for the tone conversion. For example, it is possible to use tone curves TCa, TCb, or TCc as shown in FIG. 17 for tone conversion. Even when these tone curves TCa, TCb, and TCc are used, it is possible to perform tone conversion that increases lightness.

F1. Tone Curve Variation 1:

The tone curve TCa is different from the tone curve TC of FIG. 14 in that when the input color component value I_{X} is the same or less than the shadow reference value I_{L}, the output color component value O_{X} is 0. By using this tone curve TCa, the color in the predetermined range that contains achromatic colors is changed to black (R=G=B=0) when the lightness is the same or less than a predetermined lightness threshold (R=G=B=I_{L}). This black color is formed by ink dots of the maximum amount of black ink (K), so there is improvement in the quality of the black text part when printing an input image that contains black text.

F2. Tone Curve Variation 2:

The tone curve TCb is different from the tone curve TC of FIG. 14 in that the input color component value I_{X} is a smooth curve with a full range from 0 to 255. With this tone curve TCb, the output color component value O_{X} in the overall range of the input color component value I_{X} is greater than the input color component value I_{X}, so color adjustment is performed so that the lightness is high regardless of the highness or lowness of the lightness level. When the tone curve TCb is used for the tone conversion, the changes in tones with the highlight reference value I_{H} becomes smooth, so there is improvement in the quality of images of areas for which the lightness changes continuously.

F3. Tone Curve Variation 3:

The tone curve TCc is different from the tone curve TCb in that in the range for which the input color component value I_{X} is 0 to the middle reference value I_{M}, the output color component value O_{X} is smaller than the input color component value I_{X}. With this tone curve TCc as well, the tone change is smooth for the highlight reference value I_{H}, so there is improvement in the quality of images in the area for which the lightness continuously changes. With use of the tone curve TCc as well, the output color component value O_{X} is smaller than the input color component value I_{X} in the range for which the input color component value I_{X} is smaller than the middle reference value I_{M}, so when the lightness is the same or less than a predetermined lightness threshold (R=G=B=I_{X}), it is possible to perform tone conversion that reduces the lightness. Because of this, there is improvement in the quality of the black text part when printing input images that contain black text with low lightness.

G. Modifications:

The present invention is not limited to the aforementioned embodiments and working examples, and may be reduced to practice in various other modes without departing from the scope and spirit thereof, such as the following modifications, for example.

G1: Modification 1:

In the first and second embodiments hereinabove, processing is performed with colors for which the lightness Y and the saturation S are respectively the same or less than predetermined thresholds Yt and St as the ink color K (black) neighborhood colors. But any method which determines whether a color is an ink color K neighborhood color can be used. For example, it is also possible to perform processing with colors for which the lightness color Y is the same or less than the lightness threshold Yt as the ink color K neighborhood colors, without regard to the saturation S. In this case, this is preferable to the first and second embodiments in terms of the color adjustment process or the color conversion lookup table generating process being easy.

G2: Modification 2:

In the first embodiment hereinabove, the color adjustment unit 240 converts the ink color K (black) neighborhood colors to the ink color K, but it is also possible to convert any specific color neighborhood color to the specific color. In this case, the color adjustment unit 240 may replace the color component value of the target pixel with the color component value of the specific color in cases when the color difference ΔE between the color of the target pixel and the specific color is the same or less than the color difference threshold δ.

G3: Modification 3:

In the first through third embodiments hereinabove, the quality of the output image was improved by the color converters 224 and 224a using either the color adjustment unit 240 or the lookup table generating unit 242. But any color converter which is able to output the same output value in relation to the specific color and the specific color neighborhood color input values can be used for improvement of the output image quality. For example, the color converter may also output the same output value in relation to the ink color K neighborhood colors using the color adjustment unit 240 of the first embodiment, and outputs the same output value as the ink color CMY in relation to the other ink colors CMY neighborhood colors using the lookup table generating unit 242 of the third embodiment. In this way, it is possible to perform more suitable color adjustment on black (ink color K) for which the color change effect is large, and to shorten the image processing time for other ink colors.

G4: Modification 4:

In the fourth and fifth embodiment hereinabove, the quality of output images is improved by the color converters 224 or 224a using either the color adjustment unit 240 or the lookup table generating unit 242. But for improvement in the output image quality, it is applicable as long as it is possible to increase the lightness of colors, which is represented by the output values, for input values representing colors in a predetermined range containing achromatic colors. For example, the color converter can also perform color conversion using the color converter 224 of the first embodiment on the input values that show colors with higher lightness than a predetermined value, and to perform color conversion using the color converter 224a of the second embodiment on input values that show colors with lightness lower than a predetermined value. In this way, more suitable color adjustment is performed in areas of high lightness for which there is a strong background removal effect, and it is possible to shorten the image processing time for areas of low lightness.

G5: Modification 5:

In the embodiments hereinabove, image data represented by the RGB color system is input to the printing data generating units 220 and 220a, but it is also possible to input image data represented by any color system as long as the data is able to express a color image. For example, a color system such as the L*a*b* color system and the YCbCr color system can be used for representing image data.

G6: Modification 6:

In the embodiments hereinabove, the printer 130 uses four types of ink, CMYK, but instead of this, it is also possible to use any plurality of types of ink. In this case, any look up table is applicable as long as the color conversion lookup table 232, LUT, or the color conversion source lookup table 232a can output color conversion values with a color system that corresponds to the plurality of types of ink amounts in relation to the input of the image data color system supplied to the printing data generating unit 220 and 220a.

G7: Modification 7:

In the embodiments hereinabove, a printing data generating unit 220 and 220a are used for the SPC complex 100. But the printing data generating units 220 and 220a is applicable for any processing device that performs printing data generation. In this case, for example, the printing data generating units 220 and 220a may also be incorporated in a printer driver executed on a personal computer.

Although the present invention has been described and illustrated in detail, it is clearly understood that the same is by way of illustration and example only and is not to be taken by way of limitation, the spirit and scope of the present invention being limited only by the terms of the appended claims.

1. A color conversion method for converting color in a first color system representing color of input image data to color in a second color system representing amounts of a plurality of inks used for printing, the method comprising the steps of:
(a) providing a color conversion lookup table for use in converting color component values of the first color system to color component values of the second color system; and
(b) executing color conversion to generate an output value consisting of color component values of the second color system from an input value consisting of color component values of the first color system by referencing the color conversion lookup table, wherein a same output value is generated from different input values representing different colors in predetermined color range in the first color system.

2. A color conversion method according to claim 1, wherein the input values from which the same output value is generated represents a specific color in the first color system and neighborhood colors being neighborhood of the specific color.

3. A color conversion method according to claim 2, wherein the step (b) includes a step of changing input values of the neighborhood colors to input value of the specific color, thereby generating the same output value for the specific color and the neighborhood colors.

4. A color conversion method according to claim 2, the step (a) comprising the steps of:
providing a color conversion source lookup table to output different color component values of the second color system corresponding to input of different color component values of the first color system; and
generating the color conversion lookup table by replacing color component values of the second color system corresponding to the neighborhood colors to color component values of the second color system corresponding to the specific color in accordance with the color conversion source lookup table.

5. A color conversion method according to claim 2, wherein
the output value for the specific color is a value indicating amount of one specific ink of the plurality of inks to be 100% and amount of other inks to be 0%.

6. A color conversion method according to claim 2, wherein
the neighborhood color is a color which has a color difference to the specific color less than a predetermined color difference value in a predetermined color space.

7. A color conversion method according to claim 2, wherein
the specific color is black, and the neighborhood color is a color with lightness less than a predetermined lightness value.

8. A color conversion method according to claim 7, wherein
the neighborhood color is a color with color saturation less than a predetermined saturation value.

9. A color conversion method according to claim 1, the step (b) comprising the step of
(c) executing color conversion of a high lightness mode to increase lightness of color represented by the output value which is obtained from the input value representing color in a predetermined color range containing achromatic color.

10. A color conversion method according to claim 9, the step (b) further comprising the step of executing color conversion of a reference mode to generate output values representing colors with lower lightness than colors represented by output value in the high lightness mode.

11. A color conversion method according to claim 9, wherein the step (c) includes the steps of
generating a high lightness input value representing color with a higher lightness than color represented by the input values; and
generating the output value of increased lightness from the high lightness input value by referencing the color conversion lookup table.

12. A color conversion method according to claim 11, wherein
the predetermined color range is a color range whose lightness represented by the input value is greater than a first lightness threshold.

13. A color conversion method according to claim 12, wherein the step (c) includes the steps of
generating a low lightness input value representing color with lower lightness than color represented by the input value in case that lightness of color represented by the input value is less than a second threshold which is less than the first threshold; and
generating an output value of decreased lightness from the low lightness input value by referencing the color conversion lookup table.

14. A color conversion method according to claim 9, wherein the step (c) includes the step of generating an output value representing a color with high lightness by adjusting the generated output value from the input value by referencing the color conversion lookup table.

15. A color conversion method according to claim 14, the step (a) comprising the steps of:
providing a color conversion source lookup table to generate color component values of the second color system from color component values of the first color system; and
generating the color conversion lookup table by revising the output values of the color conversion source lookup table, so as to increase lightness of the output values corresponding to the input values representing colors in the predetermined color range.

16. A color conversion method according to claim 15, wherein
the predetermined color range is a color range with lightness of the color represented by the input value being greater than the first threshold.

17. A color conversion method according to claim 16, wherein the step of generating the color conversion lookup table includes the step of revising the output value of the color conversion source lookup table, so as to decrease lightness of the output values corresponding to input values which represent lightness less than a second threshold which is less than the first threshold.

18. A color converter configured to convert color in a first color system representing color of input image data to color in a second color system representing amounts of a plurality of inks used for printing, the color converter comprising:
a color conversion lookup table for use in converting color component values of the first color system to color component values of the second color system; and
a color conversion executing unit configured to generate an output value consisting of color component values of the second color system from an input value consisting of color component values of the first color system by referencing the color conversion lookup table, wherein a same output value is generated from different input values representing different colors in predetermined color range in the first color system.

19. A computer program product for converting color in a first color system representing color of input image data to color in a second color system representing amounts of a plurality of inks used for printing, the computer program product comprising:
a computer-readable medium; and
a computer program stored on the computer-readable medium, the computer program including:
a first program for causing a computer to provide a color conversion lookup table for use in converting color component values of the first color system to color component values of the second color system; and
a second program for causing a computer to execute color conversion to generate an output value consisting of color component values of the second color system from an input value consisting of color component values of the first color system by referencing the color conversion lookup table, wherein a same output value is generated from different input values representing different colors in predetermined color range in the first color system.
